(19) United States
(12) Patent Application Publication
(10) Pub. No.: US 2009/0173981 A1
(43) Pub. Date: Jul. 9, 2009

(54) NONVOLATILE SEMICONDUCTOR STORAGE DEVICE AND METHOD OF MANUFACTURING THE SAME

(75) Inventor: Hiroyuki NITTA, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/347,036

(22) Filed: Dec. 31, 2008

(30) Foreign Application Priority Data
Jan. 9, 2008 (JP) 2008-002579

(51) Int. Cl. H01L 29/788; H01L 21/4763; H01L 21/3205

(52) U.S. Cl. 257/302; 438/586; 257/324; 438/591; 257/E29.3; 257/E21.41

(57) ABSTRACT

A nonvolatile semiconductor storage device has a first laminated portion including first insulating layers and first conductive layers laminated alternately, and a second laminated portion provided on an upper surface of the first laminated portion and including a second conductive layer formed between second insulating layers. The first laminated portion has a first semiconductor layer formed so as to contact with a gate insulating film and extend in a laminated direction. The second laminated portion has a second semiconductor layer formed so as to contact with a third insulating layer and the first semiconductor layer and extend in the laminated direction. The first semiconductor layer is of a first conductive type, and a portion of the second semiconductor layer which contacts with the side surface of the second conductive layer is of a second conductive type.

### CROSS REFERENCE TO RELATED APPLICATIONS

This application is based on and claims the benefit of priority from prior Japanese Patent Application No. 2008-2579, filed on Jan. 9, 2008, the entire contents of which are incorporated herein by reference.

### BACKGROUND OF THE INVENTION

1. Field of the Invention

The present invention relates to a nonvolatile semiconductor storage device in which data is electrically rewritable and a method of manufacturing the same.

2. Description of the Related Art

Conventionally, EEPROM (Electrically Erasable Programmable Read Only Memory) which electrically writes and erases data is known as a nonvolatile semiconductor storage device. NAND type flash memory which can be highly integrated is known as one example of EEPROM.

In order to meet a request for further shrinking of nonvolatile semiconductor storage device in recent years, a three-dimensional semiconductor storage device has been proposed in Japanese Patent Application Laid-Open No. 2005-85938. In this device, a memory cells are provided to one pillar-shaped semiconductor layer which extends in a direction vertical to a semiconductor substrate, and selection transistors are provided above and blow the memory cells.

Normally, in NAND type flash memory, a plurality of memory cells are connected in series so as to compose a NAND cell unit. However, when the memory cells and the selection transistors are provided in a vertical direction, it is technically difficult to selectively create source/drain diffusion layers of the respective memory cells on the pillar-shaped semiconductor layer as described in Japanese Patent Application Laid-Open No. 2005-85938.

For this reason, the source/drain diffusion layers are not formed on the pillar-shaped semiconductor layer, and an n− type pillar-shaped semiconductor layer is occasionally used as a channel area and a source/drain diffusion layer. In this case, a channel area just below the selection transistor becomes also the n− type semiconductor layer, and thus a threshold of the selection transistor falls. For this reason, it is difficult to obtain satisfactory cutoff characteristics. The threshold of the selection transistor may become a negative value, and a negative voltage is occasionally used for turning off the selection transistor.

### SUMMARY OF THE INVENTION

A nonvolatile semiconductor storage device according to one aspect of the present invention includes: a first laminated portion including first insulating layers and first conductive layers laminated alternately; and a second laminated portion provided on an upper surface of the first laminated portion and including a second conductive layer formed between second insulating layers, the first laminated portion including a gate insulating film including a charge storage layer for storing charges, and a first semiconductor layer formed so as to contact with the gate insulating film and extend in a laminated direction, the second laminated portion including a third insulating layer provided so as to contact with side surface of the second insulating layers and a side surface of the second conductive layer, and a second semiconductor layer formed so as to contact with the third insulating layer and the first semiconductor layer and extend in the laminated direction, and the first semiconductor layer being of a first conductive type and a portion of the second semiconductor layer provided so as to contact with the side surface of the second conductive layer being of a second conductive type, the second conductive type being inverse type of the first conductive type.

A nonvolatile semiconductor storage device according to another aspect of the present invention has a plurality of NAND cell units composed of a plurality of electrically rewritable memory cells connected in series and selection transistors connected to both ends of the memory cells, respectively, the memory cells and the selection transistors being composed of vertical transistors whose channel area is formed in a direction vertical to a surface of a substrate, the channel areas of the plurality of memory cells being first conductive type semiconductor layers, and the channel areas of the plurality of selection transistors being second conductive type semiconductor layers.

A method of manufacturing a nonvolatile semiconductor storage device, according to one aspect of the present invention, includes: sequentially depositing a plurality of first insulating layers and a plurality of first conductive layers; laminating a plurality of second insulating layers and a second conductive layer sandwiched between the second insulating layers on upper surface of the plurality of first insulating layers and the plurality of first conductive layers; piercing the first insulating layers, first conductive layers, second insulating layers and second conductive layer as laminated layers so as to form an opening; forming a gate insulating film including a charge storage layer for storing charges on side surfaces of the plurality of first insulating layers and the plurality of first conductive layers facing the opening; forming a third insulating layer on the side surfaces of the plurality of second insulating layers and the second conductive layer; forming a first conductive type first semiconductor layer so as to contact with the gate insulating film and the third insulating layer and extend in a laminated direction; and injecting second conductive type impurities into a portion of the first semiconductor layer which contacts with the side surface of the second conductive layer so as to form a second semiconductor layer which contacts with the third insulating layer and the first semiconductor layer and extends in the laminated direction.

### BRIEF DESCRIPTION OF THE DRAWINGS

FIG. 1 is a circuit diagram illustrating a nonvolatile semiconductor storage device according to an embodiment of the present invention;

FIG. 2A is a top view illustrating a concrete constitution of the nonvolatile semiconductor storage device according to the embodiment of the present invention;

FIG. 2B is a cross-sectional view taken along line A-A′ of FIG. 2A illustrating a concrete constitution of the nonvolatile semiconductor storage device according to the embodiment of the present invention;

FIG. 3A is a top view illustrating a manufacturing step for the nonvolatile semiconductor storage device according to the embodiment of the present invention;

FIG. 3B is a cross-sectional view taken along line A-A′ of FIG. 3A illustrating a manufacturing step for the nonvolatile semiconductor storage device according to the embodiment of the present invention;

FIG. 4A is a top view illustrating a manufacturing step for the nonvolatile semiconductor storage device according to the embodiment of the present invention;

FIG. 4B is a cross-sectional view taken along line A-A′ of FIG. 4A illustrating a manufacturing step for the nonvolatile semiconductor storage device according to the embodiment of the present invention;

FIG. 5A is a top view illustrating a manufacturing step for the nonvolatile semiconductor storage device according to the embodiment of the present invention;

FIG. 5B is a cross-sectional view taken along line A-A′ of FIG. 5A illustrating a manufacturing step for the nonvolatile semiconductor storage device according to the embodiment of the present invention;

FIG. 6A is a top view illustrating a manufacturing step for the nonvolatile semiconductor storage device according to the embodiment of the present invention;

FIG. 6B is a cross-sectional view taken along line A-A′ of FIG. 6A illustrating a manufacturing step for the nonvolatile semiconductor storage device according to the embodiment of the present invention;

FIG. 7A is a top view illustrating a manufacturing step for the nonvolatile semiconductor storage device according to the embodiment of the present invention;

FIG. 7B is a cross-sectional view taken along line A-A′ of FIG. 7A illustrating a manufacturing step for the nonvolatile semiconductor storage device according to the embodiment of the present invention;

FIG. 8A is a top view illustrating a manufacturing step for the nonvolatile semiconductor storage device according to the embodiment of the present invention;

FIG. 8B is a cross-sectional view taken along line A-A′ of FIG. 8A illustrating a manufacturing step for the nonvolatile semiconductor storage device according to the embodiment of the present invention;

FIG. 9A is a top view illustrating a manufacturing step for the nonvolatile semiconductor storage device according to the embodiment of the present invention;

FIG. 9B is a cross-sectional view taken along line A-A′ of FIG. 9A illustrating a manufacturing step for the nonvolatile semiconductor storage device according to the embodiment of the present invention;

FIG. 10A is a top view illustrating a manufacturing step for the nonvolatile semiconductor storage device according to the embodiment of the present invention;

FIG. 10B is a cross-sectional view taken along line A-A′ of FIG. 10A illustrating a manufacturing step for the nonvolatile semiconductor storage device according to the embodiment of the present invention;

FIG. 11A is a top view illustrating a manufacturing step for the nonvolatile semiconductor storage device according to the embodiment of the present invention;

FIG. 11B is a cross-sectional view taken along line A-A′ of FIG. 11A illustrating a manufacturing step for the nonvolatile semiconductor storage device according to the embodiment of the present invention;

FIG. 12A is a top view illustrating a concrete constitution of a nonvolatile semiconductor storage device according to a comparative example;

FIG. 12B is a cross-sectional view taken along line B-B′ of FIG. 12A illustrating a concrete constitution of the nonvolatile semiconductor storage device according to the comparative example; and

FIG. 13 illustrates a modified example according to the embodiment of the present invention.

### DETAILED DESCRIPTION OF THE EMBODIMENTS

An embodiment of the present invention will be described below with reference to the accompanying drawings. The following embodiment describes a first conduction type as n type and a second conduction type as p type. “n+ type” described below means a semiconductor whose n type impurity concentration is high, and “n− type” means a semiconductor whose n type impurity concentration is low. Similarly, “p+ type” and “p− type” mean a semiconductor whose p type impurity concentration is high and a semiconductor whose p type impurity concentration is low, respectively.

(Circuit Configuration of Nonvolatile Semiconductor Storage Device)

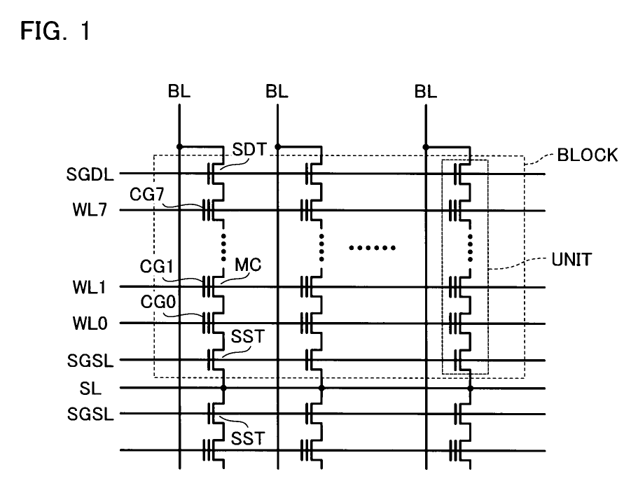

FIG. 1 is a circuit diagram illustrating a nonvolatile semiconductor storage device according to the embodiment of the present invention. The nonvolatile semiconductor storage device according to the embodiment is a so-called NAND type flash memory.

As shown in FIG. 1, one unit as a data erasing unit includes a plurality of memory cells MC connected in series, source-side selection transistor SST connected to one terminal (source side) of the memory cells MC in series, and drain-side selection transistor SDT connected to the other terminal (drain side) in series. In an example shown in FIG. 1, the eight memory cells MC are connected in series. The number of memory cells MC is eight in FIG. 1, but a different number of memory cells MC may be connected.

Word lines WL0 to WL7 are connected to control gates CG0 to CG7 of memory cell transistors as the memory cells MC. A source-side selection gate line SGSL is connected to gate terminal of the source-side selection transistor SST. A source line SL is connected to source terminal of the source-side selection transistor SST. A drain-side selection gate line SGDL is connected to gate terminal of the drain-side selection transistor SDT. A bit line BL is connected to drain terminal of the drain-side selection transistor SDT.

The source-side selection gate line SGSL and the drain-side selection gate line SGDL are used for controlling on/off of the selection transistor SST and SDT. The source-side selection transistor SST and the drain-side selection transistor SDT function as gates which supply certain potential to the memory cells MC in the unit at the time of data writing and data reading.

A plurality of units are arranged in a row direction (a direction where word lines WL shown in FIG. 1 extend) so as to compose a block. In one block, the plurality of memory cells MC connected to the common word line WL are treated as one page, and data writing and data reading operations are performed on each page.

(Concrete Constitution of the Nonvolatile Semiconductor Storage Device according to the Embodiment)

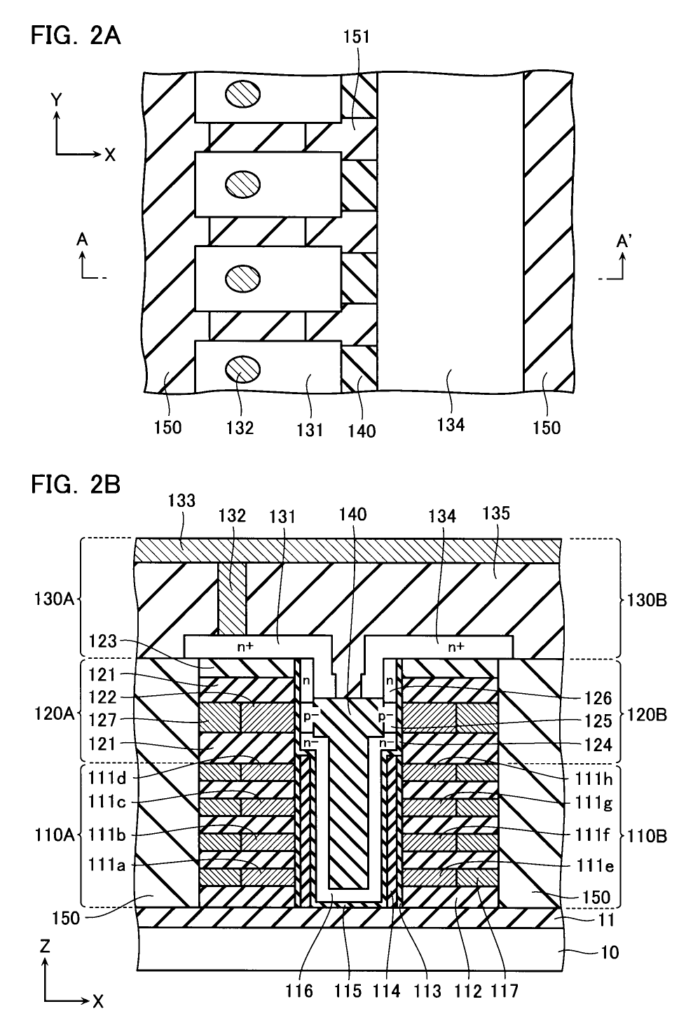

A concrete constitution of the nonvolatile semiconductor storage device according to the embodiment will be described below with reference to FIGS. 2A and 2B. FIG. 2A is a top view illustrating the nonvolatile semiconductor storage device according to the embodiment, and FIG. 2B is a cross-sectional view taken along line A-A′ in FIG. 2A. In FIG. 2A, bit lines BL (wiring layer 133, mentioned later) provided to an upper part and an insulating layer 135, described later are omitted. In FIGS. 2A and 2B, a direction in which the bit lines BL extend is determined as an X direction, and a direction in which the source line SL (a wiring layer 134, described later) extends is determined as a Y direction. A direction in which each layer is laminated (laminated direction) is determined as a Z direction.

As shown in FIGS. 2A and 2B, the nonvolatile semiconductor storage device according to the embodiment is an NAND type flash memory having an SOI (Silicon On Insulator) structure. Vertical memory cell transistors and vertical selection transistor are used as the memory cells MC and the selection transistors SST and SDT according to the embodiment. The vertical transistor is a transistor in which a channel is formed in a direction (Z direction) vertical to a surface of the semiconductor substrate.

An insulating layer 11 made of an aluminum oxide (Al₂O₃) film is formed on a substrate 10. A pair of first laminated portions 110A and 110B is formed on the insulating layer 11. The memory cells MC are formed in the first laminated portions 110A and 110B.

A second laminated portion 120A and a third laminated portion 130A are laminated on the first laminated portion 110A. Similarly, a second laminated portion 120B and a third laminated portion 130B are laminated on the first laminated portion 110B. The selection transistors SDT and SST are formed respectively in the second laminated portions 120A and 120B. A contact plug layer and a wiring layer are formed in the third laminated portions 130A and 130B.

The first laminated portion 110A, the second laminated portion 120A and the third laminated portion 130A are formed so as to be separated from the first laminated portion 110B, the second laminated portion 120B and the third laminated portion 130B by a certain length in the X direction. An insulating layer 140, an insulating layer 150 and an insulating layer 151 are deposited on outer peripheries of the first laminated portion 110A, the second laminated portion 120A, the third laminated portion 130A, the first laminated portion 110B, the second laminated portion 120B and the third laminated portion 130B. The insulating layer 140 is an SOI insulating layer which is formed in a position sandwiched between the first laminated portions 110A and 110B and between the second laminated portions 120A and 120B so as to form one NAND cell unit. More concretely, the insulating layer 140 is formed so as to be buried into a U-shape portion of an n− type semiconductor layer 116, mentioned later. The insulating layer 140 is formed so that its upper surface approximately matches with an upper surface of a second conductive layer 122, described later.

The insulating layers 150 are formed so as to insulate and separate the plurality of NAND cell units. The insulating layers 151 are disposed so as to insulate and separate the NAND cell units (an n− type semiconductor layer 116 and an n type semiconductor layer 126, described later) arranged in the Y direction.

The first laminated portion 110A is formed so that first conductive layers 111a to 111d and first interlayer insulating layers (first insulating layers) 112 are alternately laminated from a lower layer. The first laminated portion 110B is formed so that first conductive layers 111e to 111h and first interlayer insulating layers (first insulating layers) 112 are alternately laminated from a lower layer. The first conductive layers 111a to 111h function as the control gates CG0 to CG 7 of the memory cells MC.

The first laminated portions 110A and 110B have a block insulating layer 113, a charge storage layer 114, a tunnel insulating layer 115, and the n− type semiconductor layer (first semiconductor layer) 116 on their side surfaces where they are opposed via the insulating layer 140. These layers 113 to 115 compose a gate insulating film including the charge storage layer for retaining data of the memory cells MC. The n− type semiconductor layer 116 functions as a channel portion and source/drain of the memory cells MC.

For example, polysilicon is used as the first conductive layers 111a to 111h. In order to lower the resistance of the control gate, tungsten (W), aluminum (Al), copper (Cu) or the like may be used. The first conductive layers 111a to 111d and the first conductive layers 111e to 111h have a silicide layer 117 at end portions opposite to the sides where the first laminated portions 110A and 110B are opposed to each other in the X direction.

For example, a silicon oxide (SiO₂) film is used for the first interlayer insulating layers 112. Alternatively, BPSG (Boron Phosphorus Silicate Glass), BSG (Boron Silicate Glass) or PSG (Phosphorus Silicate Glass) obtained by mixing boron (B) or phosphorus (P) into the silicon oxide film may be used.

The block insulating layer 113 is formed so as to contact with side walls of the first conductive layers 111a to 111h and the first interlayer insulating layers 112. The block insulating layer 113 prevents diffusion of charges stored in the charge storage layer 114 to a gate electrode. For example, a silicon oxide (SiO₂) film is used as the block insulating layer 113. A film thickness of the block insulating layer 113 is about 4 nm.

The charge storage layer 114 is formed so as to contact with the block insulating layer 113 and to store charges. For example, a silicon nitride (SiN) film is used as the charge storage layer 114. A film thickness of the charge storage layer 114 is about 8 nm.

The tunnel insulating layer 115 is provided so as to contact with the charge storage layer 114. The tunnel insulating layer 115 becomes a potential barrier when charges from the n− type semiconductor layer 116 are stored to the charge storage layer 114 or charges stored in the charge storage layer 114 diffuse to the n− type semiconductor layer 116. For example, a silicon oxide (SiO₂) film is used as the tunnel insulating layer 115. The silicon oxide film has more excellent insulation than that of the silicon nitride film, and its function for preventing the diffusion of charges is preferable. A film thickness of the tunnel insulating layer 115 is about 4 nm.

That is, the block insulating layer 113, the charge storage layer 114 and the tunnel insulating layer 115 compose an ONO film (a laminated film including the oxide film, the nitride film and the oxide film).

The n− type semiconductor layer 116 has a U-shaped cross section taken along line A-A′. That is, the n− type semiconductor layer 116 has side portions which are provided so as to contact with the tunnel insulating layer 115 and extend in a laminated direction (pillar shape), and a bottom portion which is formed so as to connect bottoms of a pair of the side portions. As a result, one NAND cell unit is formed so as to have the U-shaped cross section. Upper ends of the side portions of the n− type semiconductor layer 116 comes to upper surfaces of second interlayer insulating layers 121 positioned below the second laminated portions 120A and 120B, mentioned later. The n− type semiconductor layer 116 is composed of a semiconductor material into which n type impurity with low density is injected. A plurality of n− type semiconductor layers 116 are formed so as to be insulated and separated from one another in the Y direction as shown in FIG. 2A.

The second laminated portions 120A and 120B have a constitution in which the second interlayer insulating layer (second insulating layer) 121, the second conductive layer 122, the second interlayer insulating layer 121, and a third interlayer insulating layer 123 are laminated on the first laminated portions 110A and 110B. In other words, the second conductive layer 122 is laminated between the two second interlayer insulating layers 121. The second conductive layer 122 functions as the drain-side selection gate line SGDL of the drain-side selection transistors SDT in the second laminated portion 120A. The second conductive layer 122 functions as the source-side selection control gate line SGSL of the source-side selection transistors SST in the second laminated portion 120B.

The second laminated portions 120A and 120B have a gate insulating layer (third insulating layer) 124, a p− type semiconductor layer (second semiconductor layer) 125 and the n type semiconductor layer 126 on side surfaces where the respective second conductive layers 122 are opposed via the insulating layer 140.

For example, a silicon oxide (SiO₂) film is used as the second interlayer insulating layers 121. Alternatively, BPSG (Boron Phosphorus Silicate Glass), BSG (Boron Silicate Glass) or PSG (Phosphorus Silicate Glass) obtained by mixing the boron (B) or phosphorus (P) into the silicon oxide film may be used.

For example, polysilicon is used as the second conductive layer 122. In order to reduce resistance of the control gate, tungsten (W), aluminum (AL), or copper (Cu) may be used. The second conductive layer 122 has a silicide layer 127 on an end portion opposite to a side where the second laminated portions 120A and 120B are opposed in the X direction.

For example, an aluminum oxide (Al₂O₃) film is used as the third interlayer insulating layer 123.

The gate insulating layer 124 is provided so as to contact with side walls of the second conductive layer 122, the second interlayer insulating layers 121 and the third interlayer insulating layer 123. The p− type semiconductor layer 125 is a semiconductor layer into which p type impurity with low density is injected. One side surface of the p− type semiconductor layer 125 contacts with the gate insulating layer 124, its other side surface contacts with the insulating layer 140, and its lower surface contacts with the n− type semiconductor layer 116. Positions of the lower surface and the upper surface of the p− type semiconductor layer 125 approximately match with positions of the lower surface and the upper surface of the second conductive layer 122. That is, in the embodiment, the channel portions of the drain-side selection transistor SDT and the source-side selection transistor SST are constituted by the p− type semiconductor layer 125. In a relation between the n− type semiconductor layer 116 and insulating layer 140, the insulating film 140 is equivalent to a buried insulating film of so-called SOI substrate.

The n type semiconductor layer 126 is provided so that its lower surface contacts with the upper surface of the p− type semiconductor layer 125, its one side surface contacts with the gate insulating layer 124, and the other side surface is contacts with n+ type semiconductor layers 131 and 134, described later.

The third laminated portion 130A has an n+ type semiconductor layer (third semiconductor layer) 131 which is formed on the second laminated portion 120A.

One terminal of the n+ type semiconductor layer 131 is formed so as to contact with the n type semiconductor layer 126. The n+ type semiconductor layer 131 is formed into a rectangular plate shape which extends in the X direction as a longitudinal direction. A plurality of n+ type semiconductor layers 131 are arranged at certain intervals in the Y direction so as to be insulated from each other by the insulating layers 150 and 151. The n+ type semiconductor layers 131 are composed of polysilicon into which n type impurity is injected.

The third laminated portion 130A has contact plug layers 132 which are provided on the upper surfaces of the n+ type semiconductor layers 131, respectively, and a wiring layer 133 which is provided on upper surfaces of the contact plug layers 132.

The contact plug layers 132 are formed on the upper surfaces of the n+ type semiconductor layers 131 so as to extend in the laminated direction. The contact plug layers 132 are arranged on one straight line along the Y direction as shown in FIG. 2A.

The wiring layer 133 is formed so as to contact with the upper surfaces of the contact plug layers 132 in the plurality of third laminated portions 130A. The wiring layer 133 extends in the X direction shown in FIG. 2B, and functions as the bit lines BL described above.

The third laminated portion 130B has an n+ type semiconductor layer (third conductive layer) 134 which is provided onto the second laminated portion 120B. The n+ type semiconductor layer 134 is formed so as to be commonly connected to the plurality of n type semiconductor layers 126 arranged in the Y direction in the second laminated portion 120B. The n+ type semiconductor layer 134 has a function as the source line SL described above. The insulating layer 135 is formed between a bottom surface of the wiring layer 133 and the insulating layers 140 and 150.

(Manufacturing Steps for the Nonvolatile Semiconductor Storage Device According to the Embodiment)

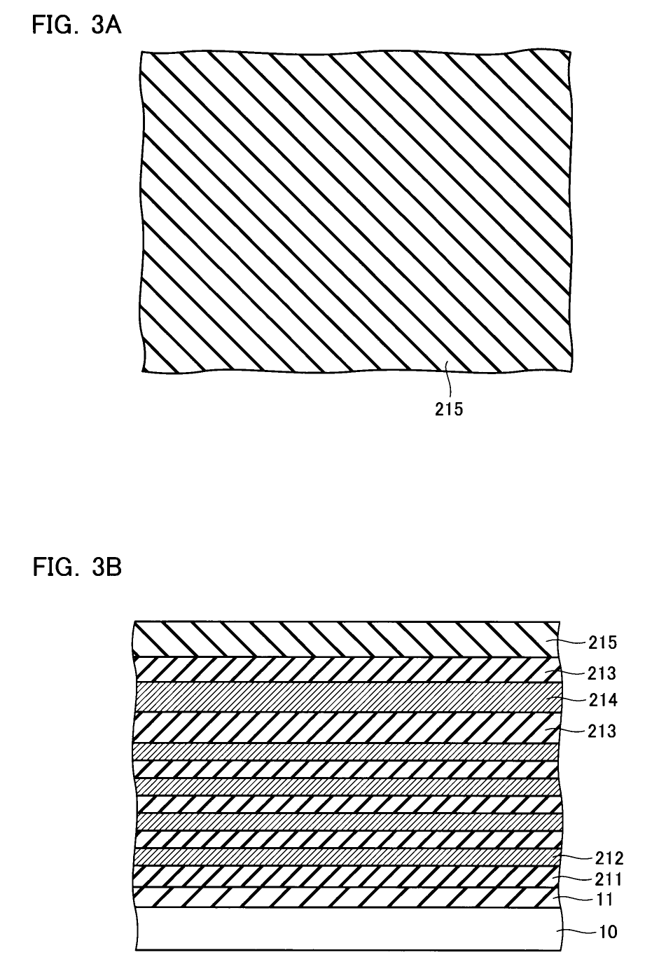

The manufacturing steps for the nonvolatile semiconductor storage device according to the embodiment will be described below with reference to FIGS. 3A to 11A and FIGS. 3B to 11B. FIGS. 3A to 11A are top views illustrating the manufacturing steps, and FIGS. 3B to 11B are cross-sectional views illustrating the manufacturing steps.

As shown in FIGS. 3A and 3B, the insulating layer 11 made of the aluminum oxide (Al₂O₃) film which becomes an etching stopper film at the time of processing the memory cells, described later, is deposited on the substrate 10. Thereafter, interlayer insulating layers 211 and first conductive layers 212 are laminated alternately. An interlayer insulating layer 213, a second conductive layer 214, the interlayer insulating layer 213 and an interlayer insulating layer 215 are sequentially deposited thereon. Moreover, a thickness of the interlayer insulating layer 213 of an upper side of the second conductive layer 214 may differ from that of a lower side of the second conductive layer 214 to adjust the selection transistor characteristics.

The respective interlayer insulating layers 211 become the first interlayer insulating layers 112 by means of a later process. The respective first conductive layers 212 become the first conductive layers 111a to 111h which function as the control gates CG0 to CG7 by means of a later process. The interlayer insulating layer 213 and the second conductive layer 214 become the second interlayer insulating layer 121 and the second conductive layer 122 which functions as the selection gate line SGDL (SGSL) of the selection transistor by means of a later process. The interlayer insulating layer 215 becomes the third interlayer insulating layer 123 by means of a later process.

In this embodiment, for example, polysilicon is used as the first conductive layer 212 and the second conductive layer 214. In order to reduce the resistance of the control gate CG, tungsten (W), aluminum (Al) or copper (Cu) may be used. For example, a silicon oxide film is used as the interlayer insulating layer 211 and the inter-layer insulating layer 213. Alternatively, BPSG (Boron Phosphorus Silicate Glass), BSG (Boron Silicate Glass) or PSG (Phosphorus Silicate Glass) obtained by mixing boron (B) or phosphorus (P) into the silicon oxide film may be used. Further, in this embodiment, the second conductive layer 214 is deposited more thickly than the first conductive layer 212 so that the selection gate electrode can obtain sufficient cutoff characteristics.

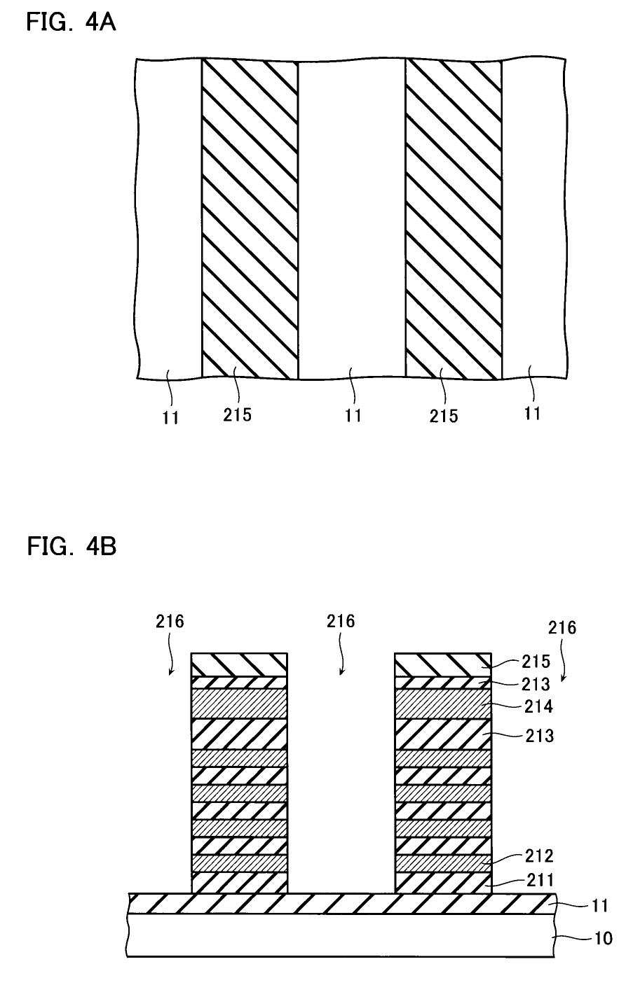

As shown in FIGS. 4A and 4B, the first conductive layers 212, the second conductive layer 214, and the interlayer insulating layers 211, 213 and 215 are selectively etched by using the interlayer insulating layer 215 as a mask according to a lithography method and an RIE (Reactive Ion Etching) method. The first conductive layers 212, the second conductive layer 214 and the interlayer insulating layers 211, 213 and 215 which are laminated are pierced to form an opening 216 so that the upper surface of the insulating layer 11 is exposed.

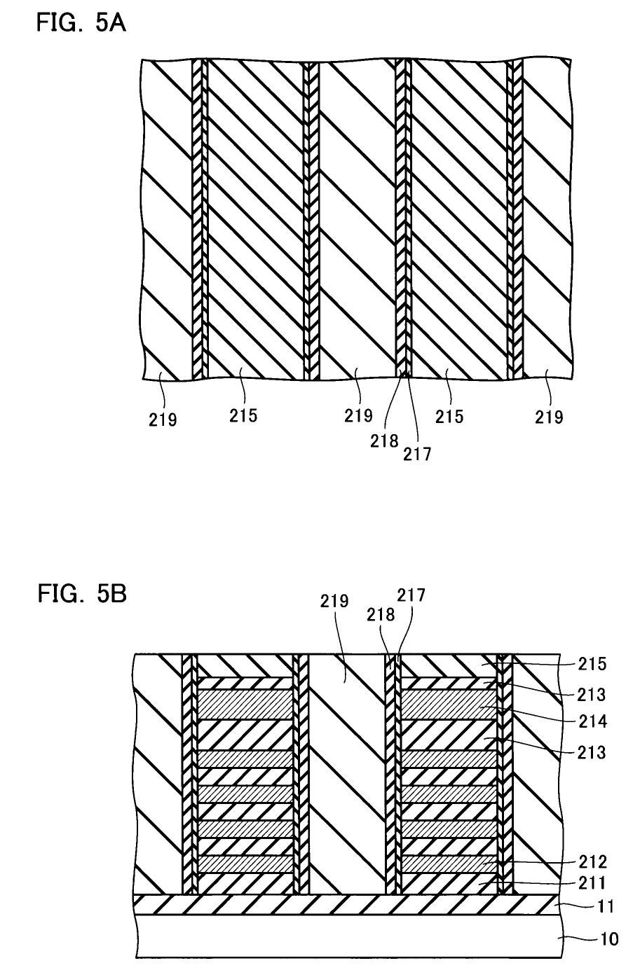

As shown in FIGS. 5A and 5B, silicon oxide films 217 and silicon nitride films 218 are deposited in this order on side surfaces of the first conductive layers 212, the second conductive layer 214 and the interlayer insulating layers 211, 213 and 215 which face the opening 216. At this time, the silicon oxide films 217 and the silicon nitride films 218 formed on the insulating layer 11 facing the opening 216 are removed by etching. The silicon oxide films 217 and the silicon nitride films 218 become the block insulating layers 113 and the charge storage layers 114 by means of a later process. Thereafter, the opening 216 is filled with a silicon oxide film 219 and is flattened by a CMP (Chemical Mechanical Polishing) method.

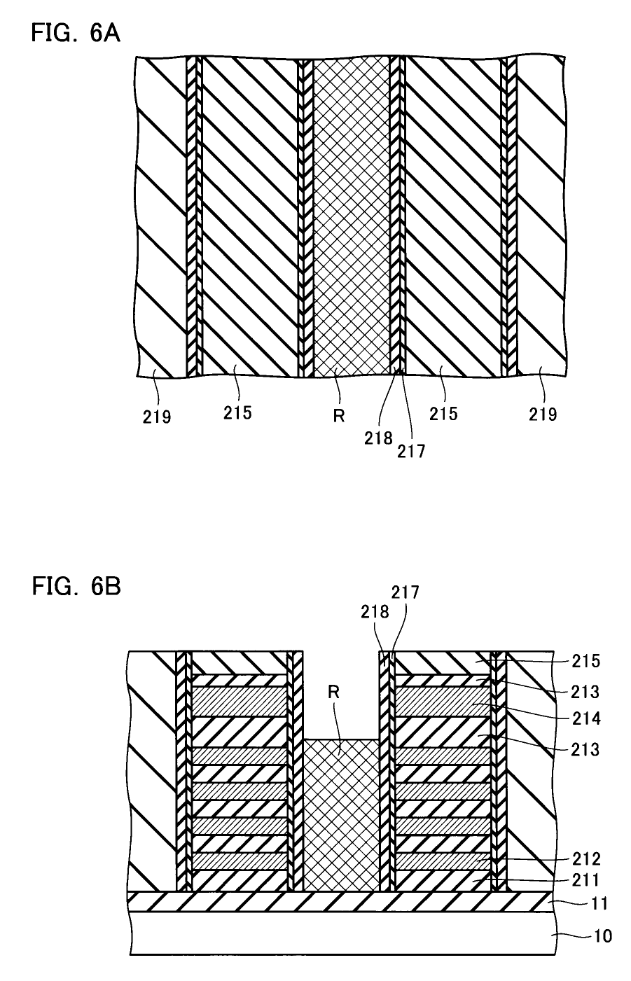

As shown in FIGS. 6A and 6B, a silicon oxide film 219 on one side (surface where the channel area is formed) of the first conductive layers 212, the second conductive layer 214 and the interlayer insulating layers 211, 213 and 215 is selectively etched by the lithography method and the RIE (Reactive Ion Etching) method. Only a portion of the opening below the bottom surface of the second conductive layer 214 is filled with resist R.

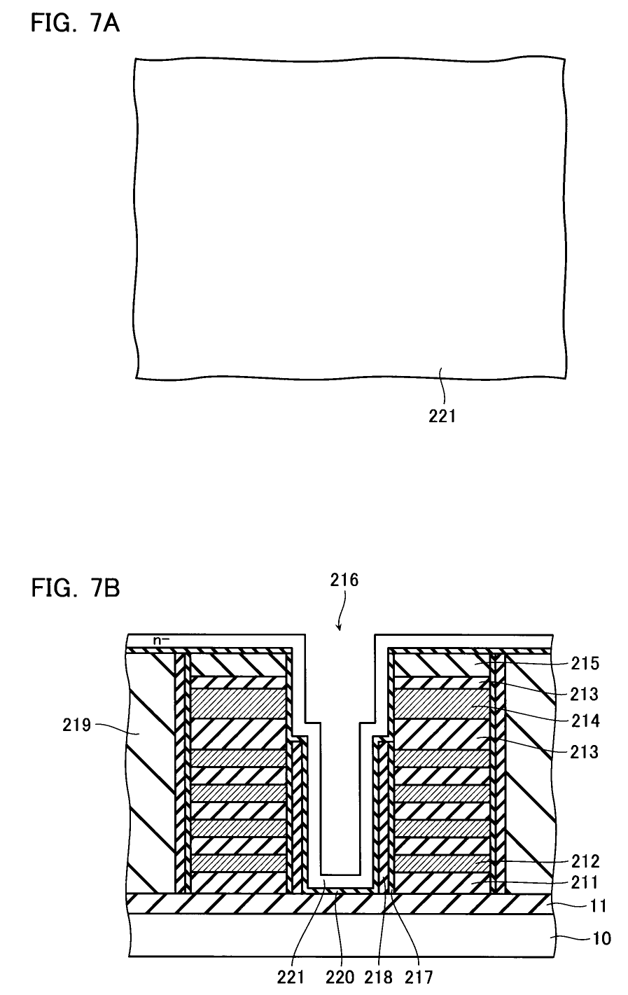

As shown in FIGS. 7A and 7B, the silicon nitride films 218 and the silicon oxide films 217 are removed by RIE using the resist R as a mask material. The silicon nitride films 218 and the silicon oxide films 217 remain only on the portion lower than the bottom surface of the second conductive layers 214 by means of this RIE method.

A silicon oxide film 220 is deposited on the silicon nitride films 218, side surfaces of the interlayer insulating layers 213 and 215 and a side surface of the second conductive layer 214. The silicon oxide film 220 becomes the tunnel insulating layer 115 and the gate insulating film 124 by means of a later process. Thereafter, an n− type semiconductor layer 221 is deposited on upper and side surfaces of the silicon oxide film 220. Amorphous silicon is deposited as the n− type semiconductor layer 221, and is annealed so as to be crystallized. n type impurities (phosphorus (P), arsenic (As) or the like) are injected into the n− type semiconductor layer 221 so that impurity concentration becomes not more than 1E19/cm³ which is comparatively low concentration. The n− type semiconductor layer 221 is subject to a later step so as to become the n− type semiconductor layer 116.

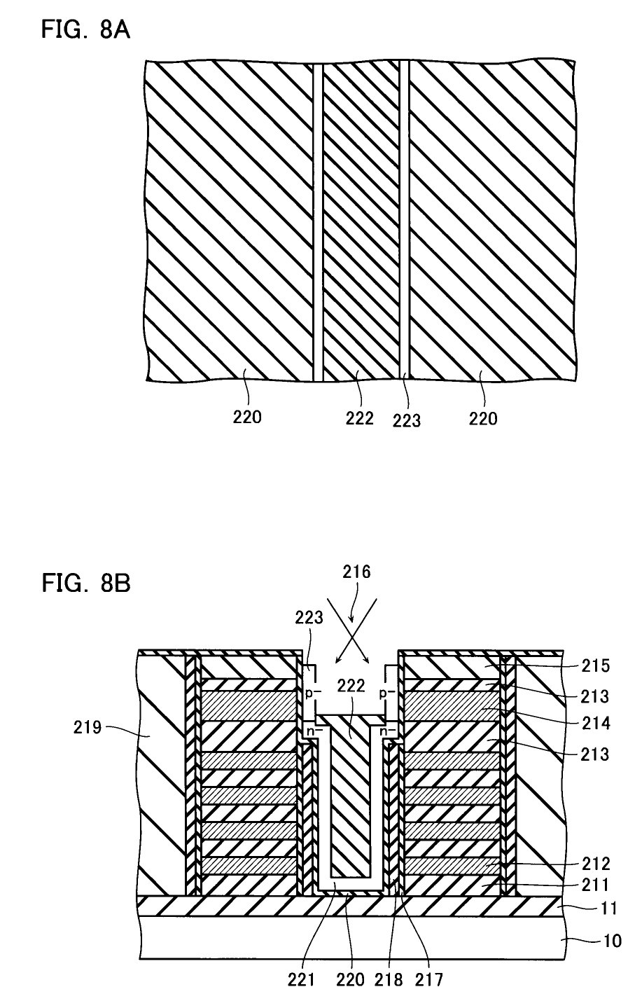

As shown in FIGS. 8A and 8B, an insulating layer 222 is deposited on the n− type semiconductor layer 221 so as to fill the opening. At this time, an upper surface of the insulating layer 222 is set to approximately the same position as the bottom surface of the second conductive layer 214. For example, a silicon oxide film is used as the insulating layer 222. The n− type semiconductor layer 221 is etched back by using anisotropic etching so as to remain on the side surfaces of the silicon oxide film 217 and the silicon oxide film 220. At this time, the n− type semiconductor layer 221 formed on a bottom surface of the opening 216 is not removed by the insulating layer 222. The n− type semiconductor layer 221 formed on the upper portion of the opening 216 may also be etched back. However, the n− type semiconductor layer 221 is formed so that its upper end is not below an upper surface of the second conductive layer 214.

A p type impurity (boron (B) or the like) with low concentration is injected into the n− type semiconductor layer 221 formed above the upper surface of the insulating layer 222 from an oblique direction by an ion implantation method. When ions are activated by annealing, p− type semiconductor layers 223 as the channel areas of the selection transistors SST and SDT are formed in the n− type semiconductor layer 221 above the upper surface of the insulating layer 222. That is, the p− type semiconductor layer 223 becomes the p− type semiconductor layer 125 after a process describe later.

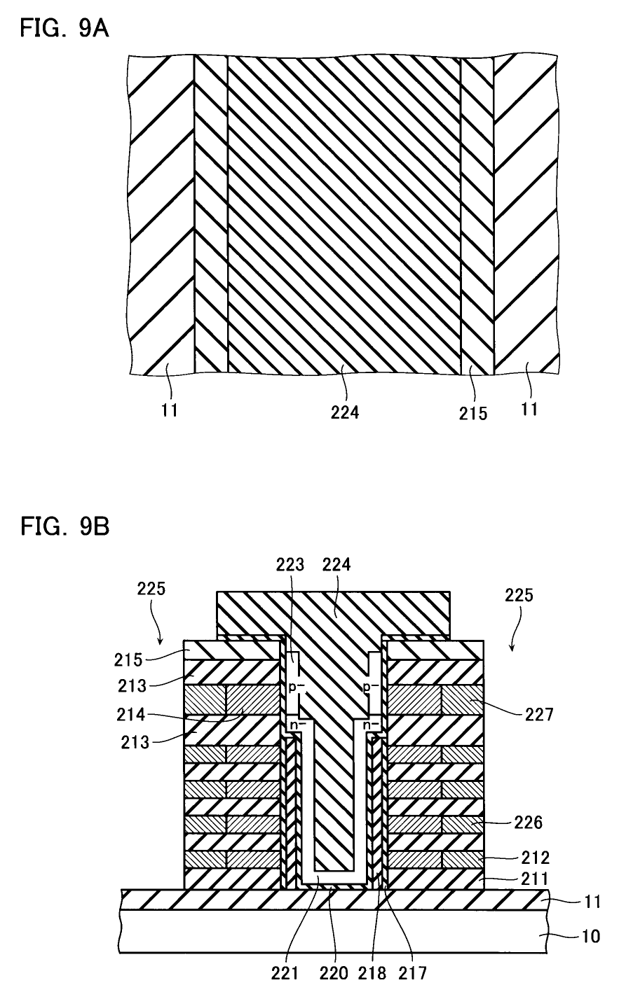

As shown in FIGS. 9A and 9B, after the insulating layer 222 is removed, a silicon oxide film is deposited as an insulating layer 224 on an entire surface. Then, an opening 225 is formed so that end portions of the first conductive layers 212, the second conductive layer 214 and the interlayer insulating layers 211, 213 and 215 in the X direction opposite to the n− type semiconductor layer 221 are exposed. The exposed end portion of the second conductive layer 214 in the X direction and the exposed end portions of the first conductive layers 212 in the X direction are silicided by a salicide method. As a result, silicide layers 226 and 227 are formed on the end portion of the second conductive layer 214 and the end portions of the first conductive layers 212. The silicide layers 226 and 227 become silicide layers 117 and 127 after a process described later.

In addition, photoresist may be used as substitute of insulating layer 222. In this case, the photoresist may be removed by ashing. On the other hand, RIE is needed to remove the above insulating layer 222. Therefore, it is easy to process by substituting the photoresist for the insulating layer 222.

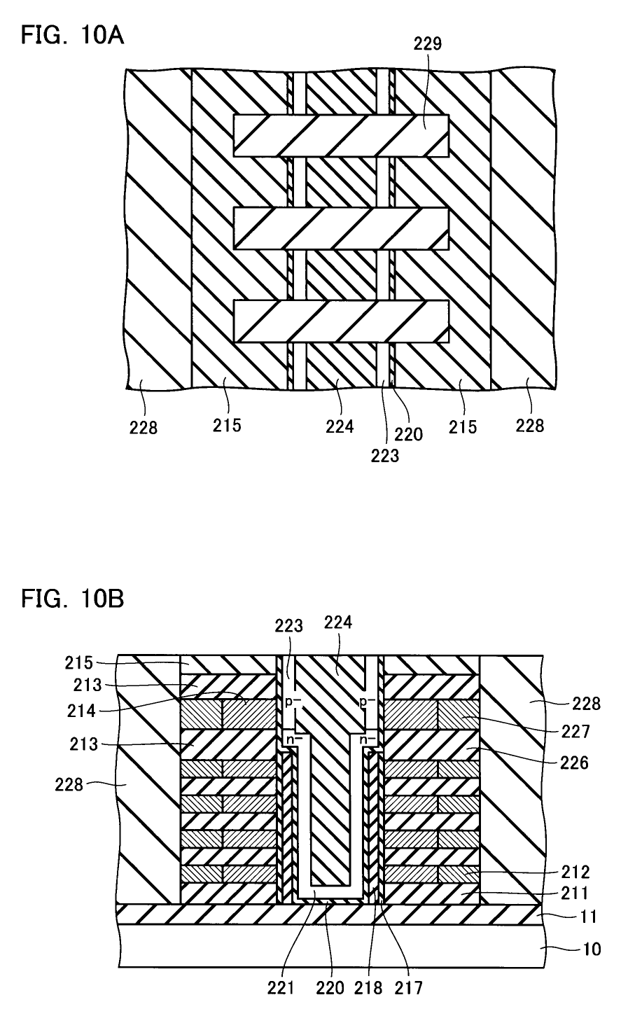

As shown in FIGS. 10A and 10B, an insulating layer 228 is deposited on the entire surface of the substrate 10 so as to be flattened by the interlayer insulating film 215 as an etching stopper. In order to electrically separate a plurality of units, after resist is formed, the first conductive layers 212, the second conductive layer 214 and the interlayer insulating layers 211, 213 and 215 are removed by etching using the interlayer insulating film 215 as a mask material. Insulating layers 229 are deposited on openings where the first conductive layers 212, the second conductive layer 214 and the interlayer insulating layers 211, 213 and 215 are removed. After that, the insulating layers 229 is flattened. Thus, as shown in FIG. 10A, p− type semiconductor layer 223 becoming the n type semiconductor layer 116 and the p− type semiconductor layer 125 after a process of described later is separated from one another by the insulating layer 229 in the Y direction as shown in FIG. 2A.

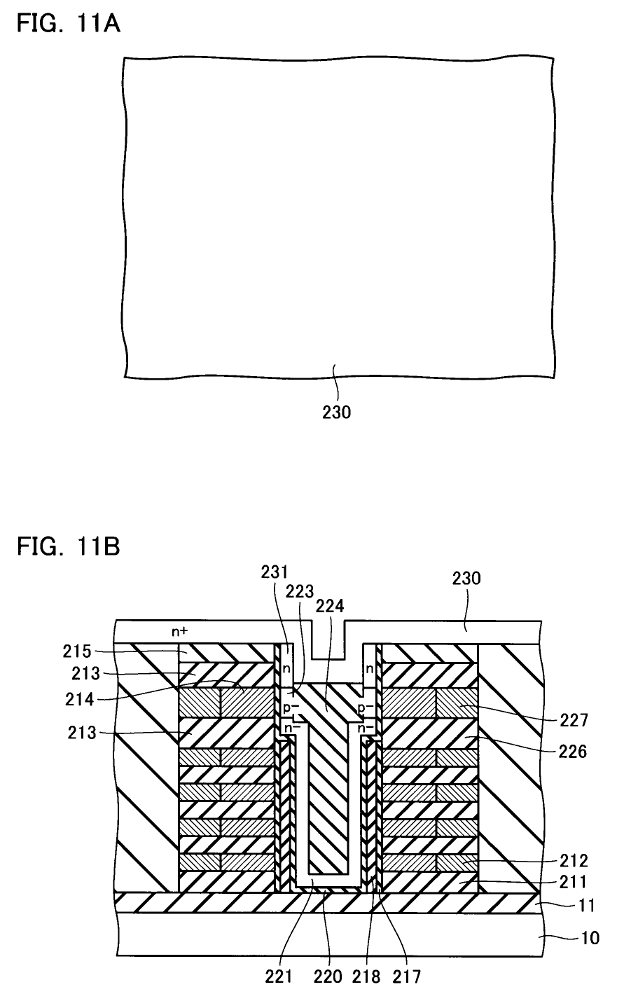

As shown in FIGS. 11A and 11B, an upper surface of the insulating layer 224 in the n− type semiconductor layer 221 is etched to a position which is approximately the same as the upper surface of the second conductive layer 214. Thereafter, an n+ type semiconductor layer 230 into which n type impurities (phosphorus (P), arsenic (As) or the like) are injected so that impurity concentration becomes not more than 1E19/cm³ which is comparatively low concentration, is deposited on an entire surface. The n+ type semiconductor layer 230 is subject to a process described later, so as to become the n+ type semiconductor layers 131 and 134. The n type impurities are diffused from the n+ type semiconductor layer 230 to the p− type semiconductor layer 223 by annealing. The p− type semiconductor layer 223 to which the n type impurities are diffused becomes an n type semiconductor layer 231. The n type semiconductor layer 231 is subject to a step described later, so as to become the n type semiconductor layer 126.

Thereafter, the n+ type semiconductor layer 230 is patterned by the lithography method, and is etched so as to become the n+ type semiconductor layers (third conductive layers) 131 and 134. When the third laminated portions 130A and 130B are formed, the nonvolatile semiconductor storage device shown in FIGS. 2A and 2B can be formed.

(Effect of the Nonvolatile Semiconductor Storage Device According to the Embodiment)

An effect of the nonvolatile semiconductor storage device according to the embodiment will be described below. In the nonvolatile semiconductor storage device according to this embodiment, since the memory cells MC and the selection transistors are vertical type and laminated, the area of the NAND type flash memory can be reduced.

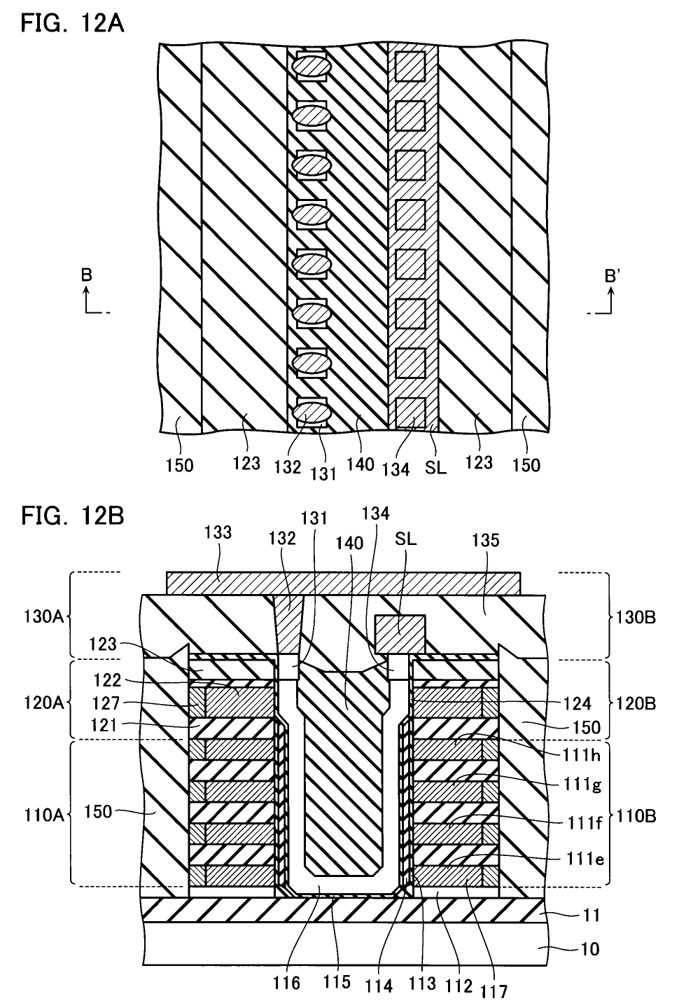

FIGS. 12A and 12B illustrate the nonvolatile semiconductor storage device according to a comparative example. FIG. 12A is a top view illustrating the nonvolatile semiconductor storage device according to the comparative example, and FIG. 12B is a cross-sectional view taken along line B-B′ of FIG. 12A. In the semiconductor storage device according to the comparative example, the same portions having the constitution similar to that in this embodiment shown in FIGS. 2A and 2B are denoted by the same symbols, and the description thereof is omitted.

The nonvolatile semiconductor storage device according to the comparative example shown in FIGS. 12A and 12B is different from the nonvolatile semiconductor storage device according to this embodiment in that it does not have the p− type semiconductor layer (second semiconductor layer) 125. Another difference is that the n+ type semiconductor layer 131 does not have a rectangular shape whose longitudinal direction is the X direction.

According to this embodiment, an impurity profile of the semiconductor layer formed on the side wall of the second conductive layer 122 can be selectively set to p− type impurity. For this reason, a threshold of the selection transistor can be easily set, and more satisfactory cutoff characteristics can be obtained. That is, according to this embodiment, a threshold voltage of the selection transistor in the nonvolatile semiconductor storage device can be set to a sufficiently high value, and thus the selection transistor having satisfactory cutoff characteristics can be provided.

Furthermore, the nonvolatile semiconductor storage device according to the embodiment has a rectangular-shaped n+ type semiconductor layer 131 whose longitudinal direction is the X direction. The contact plug layer 132 and the n+ type semiconductor layer 131 can be easily aligned, and thus, the contact plug layer 132 does not have to have a small diameter. Deterioration in yield due to misalignment of the contact plug layer 132 and the n+ type semiconductor layer 131 can be suppressed.

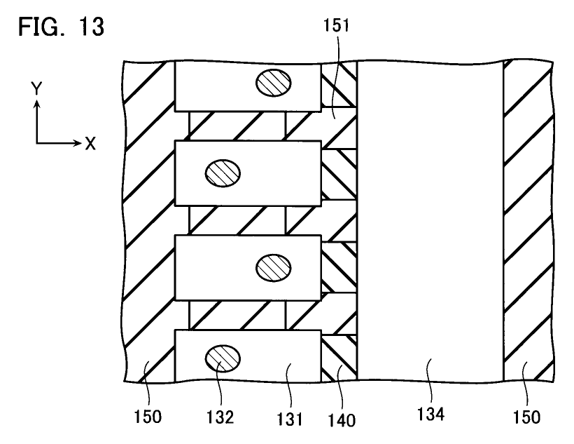

The nonvolatile semiconductor storage device according to one embodiment has been described above, but the present invention is not limited to the above embodiment, and various changes, addition and replacement can be made without departing from the purpose of the present invention. For example, as shown in FIG. 13, the contact plug layers 132 are not arranged in one straight line along the Y direction but can be arranged so that the positions in the X direction slightly shift from each other. In such a constitution, since a certain gap is provided between the contact plug layers 132, short circuit between the contact plug layers 132 is suppressed, and a misoperation can be suppressed.

What is claimed is:

1. A nonvolatile semiconductor storage device comprising:
a first laminated portion including first insulating layers and first conductive layers laminated alternately; and
a second laminated portion provided on an upper surface of the first laminated portion and including a second conductive layer formed between second insulating layers,
the first laminated portion including
a gate insulating film including a charge storage layer for storing charges, and
a first semiconductor layer formed so as to contact with the gate insulating film and extend in a laminated direction,
the second laminated portion including
a third insulating layer provided so as to contact with side surface of the second insulating layers and a side surface of the second conductive layer, and
a second semiconductor layer formed so as to contact with the third insulating layer and the first semiconductor layer and extend in the laminated direction, and
the first semiconductor layer being of a first conductive type and a portion of the second semiconductor layer provided so as to contact with the side surface of the second conductive layer being of a second conductive type, the second conductive type being inverse type of the first conductive type.

2. The nonvolatile semiconductor storage device according to claim 1, wherein the first semiconductor layer is formed so that a cross-sectional shape has a U shape in a trench formed in the first laminated portion.

3. The nonvolatile semiconductor storage device according to claim 2, further comprising a buried insulating film which is buried into the U-shaped portion of the first semiconductor layer,
wherein an upper surface of the buried insulating film approximately matches with an upper surface of the second conductive layer.

4. The nonvolatile semiconductor storage device according to claim 1, wherein the first semiconductor layer and the second semiconductor layer are formed of amorphous silicon into which different impurities are injected.

5. The nonvolatile semiconductor storage device according to claim 1, wherein positions of a lower surface and an upper surface of the second semiconductor layer approximately match with positions of a lower surface and an upper surface of the second conductive layer.

6. The nonvolatile semiconductor storage device according to claim 1, wherein the first conductive type is n type and the second conductive type is p type.

7. The nonvolatile semiconductor storage device according to claim 1, wherein
a plurality of memory cells formed in the first laminated portion and connected in series, and selection transistors formed in the second laminated portion and connected to terminal portions of the memory cells connected in series, and
the second semiconductor layer is a channel area of the selection transistors.

8. The nonvolatile semiconductor storage device according to claim 1, further comprising:
a third semiconductor layer which is connected to the second semiconductor layer,
wherein the third semiconductor layer connected to a bit line is formed for each of the plurality of second semiconductor layers arranged in a first direction, and
the third semiconductor layer connected to a source line is connected commonly to the plurality of second semiconductor layers arranged in the first direction.

9. The nonvolatile semiconductor storage device according to claim 8, further comprising:
contacts connecting the third semiconductor layers and the bit lines,
wherein the contacts are formed so as to be arranged in one line along the first direction.

10. The nonvolatile semiconductor storage device according to claim 8, further comprising:
contacts connecting the third semiconductor layers and the bit lines,
wherein the contacts are arranged so that positions in a second direction perpendicular to the first direction are different from each other.

11. The nonvolatile semiconductor storage device according to claim 1, wherein the first conductive layer is formed of polysilicon partially silicided.

12. The nonvolatile semiconductor storage device according to claim 1, wherein the second conductive layer is formed of polysilicon partially silicided.

13. A nonvolatile semiconductor storage device having a plurality of NAND cell units composed of a plurality of electrically rewritable memory cells connected in series and selection transistors connected to both ends of the memory cells, respectively,
the memory cells and the selection transistors being composed of vertical transistors whose channel area is formed in a direction vertical to a surface of a substrate,
the channel areas of the plurality of memory cells being first conductive type semiconductor layers, and
the channel areas of the plurality of selection transistors being second conductive type semiconductor layers.

14. The nonvolatile semiconductor storage device according to claim 13, wherein in the memory cells, an ONO film is used as a gate insulating film including a charge storage layer for storing charges.

15. The nonvolatile semiconductor storage device according to claim 13, wherein the first conductive type is n type and the second conductive type is p type.

16. A method of manufacturing a nonvolatile semiconductor storage device, comprising:
sequentially depositing a plurality of first insulating layers and a plurality of first conductive layers;
laminating a plurality of second insulating layers and a second conductive layer sandwiched between the second insulating layers on upper surface of the plurality of first insulating layers and the plurality of first conductive layers;
etching the first insulating layers, first conductive layers, second insulating layers and second conductive layer as laminated layers so as to form an opening;
forming a gate insulating film including a charge storage layer for storing charges on side surfaces of the plurality of first insulating layers and the plurality of first conductive layers facing the opening;
forming a third insulating layer on the side surfaces of the plurality of second insulating layers and the second conductive layer;
forming a first conductive type first semiconductor layer so as to contact with the gate insulating film and the third insulating layer and extend in a laminated direction; and
injecting second conductive type impurities into a portion of the first semiconductor layer which contacts with the side surface of the second conductive layer so as to form a second semiconductor layer which contacts with the third insulating layer and the first semiconductor layer and extends in the laminated direction.

17. The method of manufacturing a nonvolatile semiconductor storage device according to claim 16, wherein after a fourth insulating layer is deposited in the opening so that its upper surface approximately matches with a bottom surface of the second conductive layer, the second conductive type impurities are injected into the first semiconductor layer formed above the upper surface of the fourth insulating layer from an oblique direction.

18. The method of manufacturing a nonvolatile semiconductor storage device according to claim 16, wherein forming the gate insulating film, further comprising:
forming the charge storage layer on the side surface of the plurality of first insulating layers, the plurality of first conductive layers, the plurality of second insulating layers and the second conductive layer facing the opening,
burying mask material in the opening at a portion lower than a bottom surface of the second conductive layer,
removing the charge storage layer using the mask material,
forming the third insulating layer on a side surface of the charge storage layer.

19. The method of manufacturing a nonvolatile semiconductor storage device according to claim 16, further comprising: partially siliciding the first conductive layers and the second conductive layer.
